(19) United States
(12) Patent Application Publication
(10) Pub. No.: US 2013/0020549 A1
(43) Pub. Date: Jan. 24, 2013

(54) SYSTEMS AND METHODS FOR FABRICATING LONGITUDINALLY-SHAPED STRUCTURES

(71) Applicants: Hongfei Liu, Singapore (SG); Wei Liu, Singapore (SG); Soo Jin Chua, Singapore (SG); Chew Beng Soh, Singapore (SG)

(72) Inventors: Hongfei Liu, Singapore (SG); Wei Liu, Singapore (SG); Soo Jin Chua, Singapore (SG); Chew Beng Soh, Singapore (SG)

(73) Assignee: Agency for Science, Technology and Research, Connexis (SG)

(21) Appl. No.: 13/532,736

(22) Filed: Jun. 25, 2012

(30) Foreign Application Priority Data
Jun. 24, 2011 (SG) 201104702-4

(51) Int. Cl. H01L 21/20; H01L 29/06; B82Y 40/00; B82Y 99/00

(52) U.S. Cl. 257/9; 438/478; 977/700; 257/E21.09; 257/E29.024

(57) ABSTRACT

The present invention relates, in some aspects, to systems and methods for fabricating longitudinally-shaped structures such as nanobelt semiconductor structures. In some embodiments, the method comprises:
a) providing a substrate selected to promote epitaxial growth thereon a selected growth orientation, b) depositing a crystalline sacrificial layer on the substrate for epitaxially growing along the selected growth orientation, c) forming a film over the sacrificial layer, the film having a crystal lattice structure grown substantially along the selected growth orientation, and d) removing at least part of the sacrificial layer, thereby producing the longitudinally shaped structures from the film by strain redistribution through the crystal lattice structure of the film to crack the film along a selected in-plane axis of the selected growth orientation.

### PRIORITY CLAIM

This application claims priority to Singaporean application number 201104702-4, filed Jun. 24, 2011, incorporated herein by reference.

### TECHNICAL FIELD

The present invention relates, in some aspects, to systems and methods for fabricating longitudinally-shaped structures such as nanobelt semiconductor structures.

### BACKGROUND

Semiconductor structures, in particular nanostructures, have long been attracting academic and industry interest because of their novel properties such as their reduced size, increased surface-to-volume ratio, and increased quantum confinement effects.

In terms of geometrical structures, commonly available semiconductor structures can be classified into two main groups: hollow tubes and solid wires, both of which have a circular symmetric cross section. Less common is a third group of semiconductor structures which may be referred to as nanobelts and which have a rectangular cross section. These semiconductor structures, particularly the nano sized structures, have great potential in being applied in devices such as photovoltaic devices, detectors, transducers and sensors.

Semiconductor structures comprising a group of semiconducting oxides have been synthesized. These include, for example, ZnO-based, ZnS-based or SnO₂-based nanobelts. ZnO nanobelts have prospective applications in piezoelectric field effect transistors and piezoelectric diodes due to the unique coupling of piezoelectric and semiconducting properties of ZnO nanobelts. The combination of semiconducting and piezoelectric properties of ZnO nanostructures is of great interest for fabricating nanogenerators, such as, for example, nanoscale power generators to convert mechanical energy directly into electricity.

ZnO nanobelts are not generally stable in either acidic or alkaline conditions. Recent studies show that even moisture can have an effect on the performance of devices based on ZnO nanostructures. Further, p-type doping of ZnO is quite a challenge. In fact, the fabrication of stable and reproducible p-type ZnO remains a challenge even in controlled laboratory conditions. As a comparison, GaN, a maturely developed semiconductor, has the same wurtzite crystal structure, wide bandgap, and great piezoelectric coefficients as those of ZnO. GaN thin film and its related heterostructures have been widely used in fabricating light-emitting diodes (LED) for solid-state lighting in industry. When compared to ZnO-based semiconductor structures, GaN-based semiconductor structures are generally more stable in atmospheric and/or under acidic or alkaline conditions. Recent studies indicate that nanogenerators made of GaN nanowires may have a better performance than those made of ZnO nanowires. Unfortunately, the synthesis of GaN-based nanostructures is much more difficult than that of ZnO nanostructures. To date, the synthesis of GaN semiconductor structures, in particular nanostructures, is possible only via vapor phase deposition (VPD), which is largely dependent on the patterning of the substrates and/or the usage of catalysts. As a consequence, there exists a great challenge in controlling the crystal quality of the GaN-based nanostructures, especially the doping of the nanostructures which plays an important role in the magnitude of the piezopotential. Further, the shape of the GaN-based nanostructures is difficult to control in the VPD method. Thus, improvements in both ZnO and GaN nanostructures are still needed.

In general, controlled growth is required to control metal oxide semiconductor structures' shape, size distribution, crystal structure, defect distribution and surface structure. However, this has been difficult to achieve.

There is also a lack of techniques that are able to grow or align semiconductor structures, particularly the nanostructures, into arrays or onto patterned substrates. Such techniques would be a key step toward semiconductor systems and nanosystem integration.

There is a need to provide a method for fabricating semiconductor structures, particularly nano sized structures, that enables controlled growth of the substrates and/or films involved.

There is also a need to provide a method for forming orderly arrays of semiconductor structures, such as nanobelt structures.

### SUMMARY

According to a first aspect, there is provided a method to fabricate longitudinally-shaped structures, the method comprising
a) providing a substrate selected to promote epitaxial growth thereon along a selected growth orientation;
b) depositing a crystalline sacrificial layer on the substrate for epitaxially growing along the selected growth orientation;
c) forming a film over the sacrificial layer, the film having a crystal lattice structure grown substantially along the selected growth orientation; and
d) removing at least part of the sacrificial layer, thereby producing the longitudinally-shaped structures from the film by strain redistribution through the crystal lattice structure of the film to crack the film along a selected in-plane axis of the selected growth orientation.

The growth orientation may be selected for building up of asymmetric stress.

Advantageously, the substrate may be selected to promote the desired epitaxial growth of the crystalline sacrificial layer and any subsequent layer(s) thereon along a selected growth orientation. Advantageously, the disclosed method can be used to produce longitudinally-shaped semiconductor structures such as a semiconductor nano-belt structure.

Advantageously, as the crystalline sacrificial layer and the subsequent film layer are grown along the same selected crystal growth orientation, when the sacrificial layer is at least partially removed, strain redistribution, in particular crystal lattice relaxation, occurs in the crystal lattice structure of the film. This initiates the cracking of the film along the selected axis of the selected crystal growth orientation to provide longitudinally-shaped semiconductor structures.

According to one embodiment, there is provided a process to form an array of longitudinally-shaped semiconductor structures affixed to a desired substrate comprising
a) providing a substrate selected to promote epitaxial growth thereon along a selected growth orientation;
b) depositing a crystalline sacrificial layer on a substrate for epitaxially growing along the selected growth orientation;
c) forming a film over the sacrificial layer, the film having a crystal lattice structure grown substantially along the selected growth orientation;
d) coating the surface of the film with wax;
e) removing the crystalline sacrificial layer, thereby producing the longitudinally-shaped semiconductor structures from the film by redistributing strain through the crystal lattice structure of the film to crack the film along a selected in-plane axis of the selected growth orientation;
f) affixing the array of longitudinally-shaped semiconductor structures with the wax coating onto a desired substrate; and
g) removing the wax coating to provide an array of longitudinally-shaped semiconductor structures affixed to the desired substrate.

According to another aspect, there is provided a device comprising a plurality or an array of nanobelt semiconductor structures obtained from the methods described herein.

According to another aspect, there is provided a piezoelectric field-effect transistor comprising the nanobelt semiconductor structures obtained from the methods described herein.

According to another aspect, there is provided a piezoelectric diode comprising the nanobelt semiconductor structures obtained from the methods described herein.

According to another aspect, there is provided a nanogenerator comprising the nanobelt semiconductor structures obtained from the methods described herein.

According to another aspect, there is provided a photovoltaic device comprising the array of nanobelt semiconductor structures obtained from the methods described herein.

According to another aspect, there is provided a sensor comprising the array of nanobelt semiconductor structures obtained from the methods described herein.

According to another aspect, there is provided a detector comprising the array of nanobelt semiconductor structures obtained from the method of the first aspect.

Still other aspects of the invention are discussed in more detail below.

### Definitions

The following words and terms used herein shall have the meaning indicated:

The terms “epitaxy”, “epitaxial growth”, “epitaxially” and grammatical variants thereof are to be used interchangeably and interpreted broadly to include a process of depositing or growing a layer of crystalline material over another layer of crystalline material. In instances where the overlayer of crystalline material is different from the layer beneath, the process is referred to as ‘heteroepitaxy’. In epitaxy, the overlayer of crystal material may have one or more preferred crystallographic orientation(s) with respect to the layer beneath. In one embodiment, the overlayer of single crystal material may have the same preferred crystallographic orientation as the layer beneath. The overlayer may be referred to as an ‘epitaxial film’ or “epitaxial layer”. As to the layer beneath, it may be referred to as a ‘substrate’ or ‘substrate layer’.

The term longitudinally-shaped structure refers to any structure having a length dimension that is significantly longer than a height or width dimension.

The term “nanobelt” is to be broadly interpreted to include any generally longitudinally-shaped structure having a width and height dimension in the nano-size range of less than 1 μm. The nanobelt structure typically has a length dimension that is substantially longer than the width and height dimension and hence may have “ribbon-shaped” nanostructures.

The term “piezoelectric” as used herein refers to a device or a material that has piezoelectric properties in that an applied mechanical stress may generate a voltage (e.g. when a crystalline material with no centre of symmetry is squeezed or stretched) and, inversely, an applied voltage may change the shape of the material.

The term “dislocation” is to be interpreted broadly to include any crystallographic defect or irregularity within a crystal structure or on a crystal surface. Dislocations often occur during heteroepitaxy and can be divided into at least two types, misfit or threading dislocations. Misfit dislocations lie in the epitaxial interface and result from the lattice mismatch between two adjacent segments (e.g. the film and the substrate). Threading dislocations lie within the. epitaxial film and run from the interface through the film all the way to the film surface. Threading dislocations may be generated in response to misfit stresses at the interface and have the final configuration consisting of a misfit segment lying in the interfacial plane bounded by two segments that thread through the interface all the way to the film surface.

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

### Disclosure of Optional Embodiments

Exemplary, non-limiting embodiments of a method to fabricate longitudinally-shaped structures will now be disclosed.

The method, in these embodiments, comprises the steps of:
a) providing a substrate selected to promote epitaxial growth thereon along a selected growth orientation,
b) depositing a crystalline sacrificial layer on the substrate for epitaxially growing along the selected growth orientation,
c) forming a film over the sacrificial layer, the film having a crystal lattice structure grown substantially along the selected growth orientation, and
d) removing the sacrificial layer, thereby producing the longitudinally-shaped structures from the film by strain redistribution through the crystal lattice structure of the film to crack the film along a selected in-plane axis of the selected growth orientation.

In one embodiment, the strain redistribution may be through crystal lattice relaxation.

In one embodiment, the longitudinally-shaped structures may be nanobelt semiconductor structures.

In one embodiment, the film may have a thickness in the range of 50 to 250 nm or 100 to 200 nm.

In one embodiment, the sacrificial layer may be deposited in a manner which provides a single crystalline film of the sacrificial layer spreading in an epitaxial direction over the substrate.

In one embodiment, the sacrificial layer may be deposited on the substrate layer using techniques selected from the group consisting of: sputtering deposition, pulse laser-assisted deposition (PLD), hydrothermal solution deposition, molecular beam epitaxy (MBE) and metalorganic chemical vapor deposition (MOCVD).

It should be noted that any other techniques capable of depositing a single crystalline film of the sacrificial layer epitaxially over the Substrate may also be used.

In one embodiment, the substrate selected to allow epitaxial growth of the sacrificial layer and a subsequent layer along a selected growth orientation (e.g. with c-axis lying in the growing plane) may be selected from an r-plane sapphire substrate, a spinal silicon substrate, an a-plane GaN wafer, a m-plane GaN wafer and a GaN/r-sapphire (which is GaN template epitaxially grown on r-plane sapphire). The selection of the substrate such as a r-plane sapphire substrate is crucial to provide the epitaxial orientation growth of the sacrificial and any following layer(s).

In one embodiment, the sacrificial layer may be a metal oxide. For example, the sacrificial layer may be a zinc oxide (ZnO). In another embodiment, the sacrificial layer may comprise a silicon containing compound such as SiO₂, SiOₓ (0<x<2) and SiN. In yet another embodiment, the sacrificial layer may be AlInN in which the composition of indium is set at between 15% to 20%, or about 17.9%.

In one embodiment, the sacrificial layer may be deposited epitaxially onto the r-plane sapphire substrate using any one of the techniques described above.

In one embodiment, the sacrificial layer such as ZnO sacrificial layer may be prepared by loading r-plane sapphire substrates into a radio-frequency (rf) magnetron sputtering chamber. In this embodiment, the ZnO sacrificial layer may be first exposed to heat treatment at a temperature selected from the range of 600° C. to 700° C. for about 1 to 3 hours. Subsequently, the temperature may be lowered down to one selected from the range of 250° C. to 350° C. in order to grow a thin low-temperature ZnO buffer layer. The thickness of this ZnO buffer layer may be in the range of 5 nm to 15 nm, more preferably 8 to 12 nm. Growth of the thin low-temperature ZnO buffer may be followed by an in-situ annealing in argon ambient at a temperature selected from the range of 600° C. to 700° C. for a period selected from the range of 15 minutes to 45 minutes. This may be followed by a further growth of ZnO thin film resulting in an ZnO sacrificial layer with an overall thickness in the range of 200 nm to 1500 nm, more preferably from 250 nm to 1200 nm, still more preferably from 300 to 1000 nm. This further growth may be performed at a temperature selected from the range of 500° C. to 600° C.

The inventors have found that the thickness of the ZnO layer is an important factor contributing to the working of some embodiments of the invention. For example, the overall thickness of the ZnO sacrificial layer may be between 300 nm and 1000 nm. The inventors found that if the ZnO layer is too thin, the removal by etching process may take a longer time in some cases; and if the ZnO layer is too thick, during subsequent formation of the semiconductor layer, the ZnO layer may in some cases be damaged or corroded, which in turn may result in the semiconductor film peeling off during growth from the sacrificial ZnO layer.

In one embodiment, step b) comprises forming a semiconductor film over the sacrificial layer. Advantageously, the semiconductor film may serve as a protective layer over the sacrificial layer.

In one embodiment, step b) comprises the step of forming a semiconductor film over the ZnO sacrificial layer at a relatively low temperature.

In one embodiment, the semiconductor film may be an n- or p-type semiconductor material.

In one embodiment, the semiconductor film may be a metalloid selected from the group consisting of Group III and Group V elements of the Period Table of Elements.

In one embodiment, the semiconductor film may be a group III metal-nitride.

In one embodiment, the semiconductor film may be GaN.

In one embodiment, the method may comprise the step of selecting GaN as the protective film.

In one embodiment, the method may comprise the step of selecting GaN as the protective film.

In one embodiment, the GaN film may be formed on the ZnO sacrificial layer by loading the prepared ZnO sacrificial layer into a MOCVD reactor in nitrogen ambient and heating the MOCVD reactor to temperatures ranging from 250° C. to 650° C. The pressure of the reactor may be set to the range of 100 Torr to 200 Torr, more preferably at about 150 Torr. Subsequently, trimethyl gallium (TMGa) and ammonia may be fed into the MOCVD reactor simultaneously to start the growth of GaN at a relatively low temperature. In some cases, TMGa may be fed at a rate between 10 and 30 sccm and ammonia may be fed at a rate between 5 to 15 L/min. Due to the low temperature growth conditions used (as compared to a temperature of 1000° C. to 1050° C. used in typical GaN growth), the GaN growth tends to be three dimensional. To suppress the three dimensional growth and thereby enhance the lateral growth, Bis(cyclopentadienyl)magnesium (Cp2Mg) may be fed into the reactor. Cp2Mg may be fed at a rate varying between 100 sccm to 500 sccm, preferably at a rate of about 200 sccm. The Cp2Mg flow may be constant or modulated.

In one embodiment, the method may comprise the step of forming the protective film at a temperature selected from the range of 350° C. to 650° C.

In one embodiment, the method may comprise the step of providing a growth suppressing agent in the growing step to suppress the three dimensional growth of the GaN film.

In one embodiment, the GaN protecting layer may also be deposited using pulse laser-assisted deposition (PLD) since the deposition ambient of PLD may not have any detrimental effect on ZnO layer.

The thickness of the GaN semiconductor film may be in the range of from 30 nm to 150 nm. Advantageously, this low temperature GaN buffer layer may be used to prevent the ZnO sacrificial layer from decomposing in ammonia ambient at high temperatures. The inventors have found that the thickness of the GaN semiconductor film needs to be properly chosen in some embodiments. If the Ga film is too thin, it may not protect the ZnO layer well in some cases, and if the GaN film is too thick, it may cause deterioration of the quality of the quantum semiconductor structures of step c) in some cases.

In one embodiment, the selected growth orientation is that having the c-axis lying in the growing plane. Here, the growing plane refers to the plane of the growing material that is parallel to the substrate surface plane and perpendicular to the growth direction. The c-axis lies in the growing plane, which will be the film cracking direction for nanobelt formation. In one embodiment, step c) comprises the step of growing the GaN film and incorporating a functionally active element to thereby form a functionally active film.

In one embodiment, step c) comprises the step of selecting GaN/GaInN or GaN/AlGaN or AlGaInN/GaN as the functionally active film.

In one embodiment, step c) comprises the step of growing the GaN film along the same c-axis as the ZnO sacrificial layer. In this embodiment, after the growth of low temperature GaN buffer layer, the temperature of the MOCVD reactor may be increased to that selected from the range of 650° C. to 800° C., more preferably 700° C. to 750° C. Trimethylinidium (TMIn) may be flowed into the reactor together with TMGa and ammonia to initiate the growth of GaInN thin film. The Indium composition may be varied by changing the relative flow ratio of TMIn and TMGa. The growth rate of GaInN thin film may preferably be in the range of 100 nm per hour to 200 nm per hour. In one embodiment, the indium composition may be varied from 0 to 1.0 mole fraction within the GaInN film. In another embodiment, the indium composition may be varied from 0 to 0.5 mole fraction within the GaInN film. Advantageously, the GaInN film formed from the disclosed method may be of high crystal quality. The GaInN film thickness may be varied from 1 nm to 500 nm. In another embodiment, the GaInN film thickness may be varied from 2 nm to 500 nm while still maintaining a mirror-like surface. The GaInN film may have a mirror-like surface, which is dependent on the composition of In in the GaInN layer. For example, for a film thickness of about 500 nm, if the In content is less than 10%, the film may have a mirror-like surface.

In one embodiment, the disclosed method produces a GaInN/GaN/ZnO/r-sapphire structure.

In one embodiment, the removing step comprises etching the sacrificial layer.

In one embodiment, the ZnO sacrificial layer may be etched away using an acid solution in order to crack the GaInN/GaN structure along its c-axis lying in the surface plane to thereby generate GaN-based nanobelts.

In one embodiment, the acid solution used may be HCl or diluted HF solutions

In one embodiment, the width of the nanobelts formed from the disclosed method can be controlled via controlling the layers' thicknesses during growth, by MOCVD for example. The width of the nanobelts may be controlled by the stored stress, depending on the combination of (i) the GaN and GaInN thicknesses and (ii) the In composition in GaInN. For example, 50-nm GaN and 150-nm GaInN with In-content of ˜30% may lead to the average nanobelts width of ˜10 μm. An increase in GaInN thickness with a decrease in In-content can also result in the 10 um width.

In one embodiment, the length of the nanobelts may be controlled by controlling the sample size in the c-axis direction of growth. The length of the nanobelts may be the same as the length of the specimen along the c-axis of GaN, which can be as long as desired. For example, to reduce the processing time, a 1×1 cm² specimen can be used which results in nanobelts of 1 cm in length.

In one embodiment, before the removing step (i.e. removing the sacrificial layer), the method may comprise the step of applying a substrate having adhesive properties to the film on said sacrificial layer.

Advantageously, the adhesive properties of the substrate may allow the longitudinally-shaped structures to adhere to the substrate after the removing step.

In one embodiment, the step of applying a substrate having adhesive properties may comprise the step of coating a surface of the film with a wax in liquid form that forms a wax substrate having adhesive properties when cooled to a solid phase.

In one embodiment, the method further comprises the step of affixing longitudinally-shaped structures with the wax substrate onto a desired substrate (e.g. glass, quartz and sapphire, optionally coated with ITO).

In one embodiment, the method further comprises the step of removing the wax substrate to provide an array of longitudinally-shaped structures affixed to the desired substrate.

In one embodiment, the wax substrate may be removed using an organic solvent.

In one embodiment, there is provided a process to form an array of longitudinally-shaped semiconductor structures affixed to a desired substrate comprising
a) providing a substrate selected to promote epitaxial growth thereon along a selected growth orientation;
b) depositing a crystalline sacrificial layer on a substrate for epitaxially growing along the selected growth orientation;
c) forming a film over the sacrificial layer, the film having a crystal lattice structure grown substantially along the selected growth orientation,;
d) coating a surface of the film with a wax;
e) removing the sacrificial layer, thereby producing the longitudinally-shaped semiconductor structures from the film by redistributing strain through the crystal lattice structure of the film to crack the film along a selected axis in-plane of the selected growth orientation, the nanobelt semiconductor structures being held together by the wax coating;
f) affixing the array of longitudinal-shaped semiconductor structures with the wax coating onto a desired substrate; and
g) removing the wax coating to provide an array of longitudinal-shaped semiconductor structures affixed to the desired substrate.

In one embodiment, the longitudinal-shaped semiconductor structures may be nanobelt semiconductor structures.

In one embodiment, the process may comprise a pre-step of cutting the nanobelt semiconductor structures into specimens of desired shapes and sizes. In one embodiment, the cutting may be performed using a diamond scriber. In one embodiment wherein a GaInN/GaN/ZnO/r-sapphire structure is involved, the scribing may be performed from the sapphire substrate side to obtain a clean cleaved surface.

In one embodiment, the cut specimen may be cleaned by sonication in an organic solvent, e.g. acetone, followed by methanol and deionized water, for example.

In one embodiment, the specimen may, after cleaning, be dried using N₂ flow, followed by oven baked at a temperature of about 110° C., before cooling the specimen down to room temperature.

In one embodiment, step d) of the process may employ liquid wax to coat the semiconductor structure. In one embodiment, the coating may be performed using a glass tube. In one embodiment, the wax used for the coating may be a black wax dissolved in an organic solvent. In one embodiment, the organic solvent may be dichloromethane CH₂Cl₂.

In one embodiment, the applied liquid wax may be first left to solidify in ambient condition for a period of time ranging from 10 minutes to 1 hour. This is to provide a soft wax layer on the specimen. The specimen may then be baked, as with step b), at a temperature selected from the range of 30° C. to 150° C. for a period selected from 1 hour to 3 hours. Advantageously, this relaxes the strain in the wax. After baking, the wax is solidified.

In one embodiment, the specimen may be baked in oven at a temperature selected from the range of 50° C. to 100° C. and for a period between 30 minutes to 2 hours in step b).

In one embodiment, step e) of the disclosed process may comprise dipping the semiconductor structure into a tank containing an acid solution so as to allow the sacrificial layer to be etched off by the acid.

In one embodiment, the acid solution may be an HCl solution. In one embodiment, the HCl solution may be in a concentration range of 5% to 45%. In one embodiment, the HCl solution may be in a concentration range of 10% to 37%.

Advantageously, upon removal of the sacrificial layer, the nanobelt semiconductor structures may be cracked due to the strain redistribution and relaxation in response to the release of ZnO.

In one embodiment, stirring the acid solution containing the semiconductor structures may accelerate the etch rate.

In one embodiment, upon soaking in the acid solution, the semiconductor structures in a parallel array with the wax attached may be lifted off from the substrate and float on the acid solution when the sacrificial acid layer has been etched away.

In one embodiment, the lifted-off nanobelts with the wax attached may be transferred from the acid tank to a beaker filled with water using a glass slide. The manipulation of the lifted-off nanobelts floating on the surface of acid solution or water may be done using a pair of tweezers or a plastic stick. It should be noted that when moving the nanobelts onto the glass slide, the angle between the slide and the water surface should be as small as possible so that the film (i.e. the nanobelts with the wax attached) is not bent by the surface tension of the water.

In one embodiment, the residual acid on the lifted-off film (i.e. the wax with nanobelts attached) may be washed away by transferring the film to another beaker filled with water and repeating the process for several times.

It should be noted that the acid may be removed completely to prevent the corrosion of the holder.

In one embodiment in step f), the lifted-off nanobelts with the wax attached may be moved onto a holder with the wax facing upward.

In one embodiment, the nanobelts with the wax attached may be dried on the holder by leaving it in a clean hood for a few minutes.

In one embodiment, the nanobelts in parallel arrays may be bonded to the holder. This may then be held in a sealed container of an organic solvent in order to dissolve the wax. In one embodiment, the organic solvent may be a volatile organic solvent with a high saturation vapour pressure. The organic solvent may be CH₂Cl₂.

In one embodiment, the nanobelts structure with the wax attached may be kept above the organic solvent to allow its vapour to dissolve the wax coated onto the nanobelts.

In one embodiment, when the wax becomes soft, the nanobelts structure may be dipped into the organic solvent in order to completely remove the wax.

In one embodiment, the nanobelts structure may be a GaInN/GaN nanobelts structure. Alternatively, the nanobelts structure may be other type of nanobelts structure such as AlGaN or GaInAs or SiGe. GaInAs can be formed on GaAs (110) using AlAs as sacrificial template while SiGe can be formed on Si (110) using. n-Si as sacrificial template.

The present disclosure may also provide a device comprising a plurality, or an array, of longitudinally-shaped or nanobelt semiconductor structures obtained from the above disclosed method or process.

### BRIEF DESCRIPTION OF DRAWINGS

The accompanying drawings illustrate a disclosed embodiment and serves to explain the principles of the disclosed embodiment. It is to be understood, however, that the drawings are designed for purposes of illustration only, and not as a definition of the limits of the invention.

FIG. 1 is a schematic diagram of GaN-based nanobelts fabrication.

FIG. 2 is a scanning electron microscopy image recorded with a tilted view from a cross-section of a GaInN/GaN structure grown on ZnO/r-sapphire template by MOCVD.

FIG. 3 shows depth profiles measured by secondary ion-mass spectrometry from the GaInN/GaN hetrostructure grown on ZnO templates by MOCVD.

FIG. 4(a) is an image at 1000× magnification showing the very early wet chemical etching stage of ZnO sacrificial layer in the GaInN/GaN/ZnO-r-sapphire at 5 minutes in which the etching front is parallel to the specimen edge.

FIG. 4(b) is an image at 50× magnification showing the same sample as FIG. 4(a) at a steady-state film-cracking stage at 120 minutes.

FIG. 5(a) is an image at 500× magnification at the same stage as FIG. 4(a) showing that cracks are not generated along the etching front at this stage.

FIG. 5(b) is an image at 500× magnification showing the initial cracking stage at 40 minutes wet etching.

FIG. 6 shows SEM images of the GaInN/GaN layered nanobelts assembly collected from the solutions. The scale bar in FIG. 6(a) is 50 μm and in FIG. 6(b) is 2 μm.

FIG. 7 is a Schematic diagram of a two-end device according to one aspect of the present invention using the GaInN/GaN single nanobelt fabricated by the disclosed method. FIG. 7(a) shows a device (a) having a twist-free nanobelt. FIG. 7(b) shows a device (b) having a twisted nanobelt. FIG. 7(c) shows I-V curves measured from device (a) and device (b).

FIG. 8 shows (a) optical and (b) heat sensing responses measured under a microscope from the two-end device incorporating the GaInN nanobelts of FIG. 7.

FIG. 9 shows the lifted-off and affixed GaInN/GaN nanobelts obtained from step (10) of Example 5.

FIG. 10(a), FIG. 10(b) and FIG. 10(c) show nanobelts array affixed on a glass substrate recorded under microscope with different magnifications, obtained from step (10) of Example 5. The scale bar in FIG. 10(a) is 100 μm, the scale bar in FIG. 10(b) is 50 μm and the scale bar in FIG. 10(c) is 20 μm.

### EXAMPLES

### Example 1

### A Method to Fabricate Nanobelt Semiconductor Structures

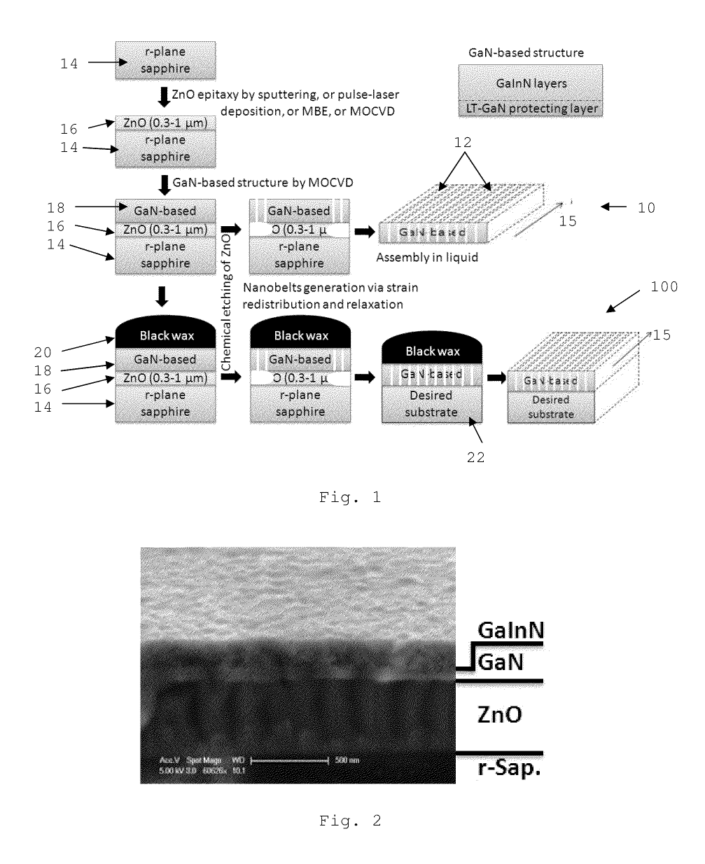

Referring to FIG. 1, there is shown a method 10 for fabricating nanobelt semiconductor structures 12. The method comprises first providing an r-plane sapphire 14, upon which an epitaxy ZnO sacrificial layer 16 may be deposited, using techniques such as sputtering, or PLD, or MBE or MOCVD. As can be seen, the ZnO sacrificial layer 16 is deposited epitaxially as a single crystalline film having a thickness in the range of 0.3 μm to 1 μm.

Over the ZnO sacrificial layer 16, a GaN-based layer 18 may be deposited by MOCVD. The ZnO sacrificial layer and the GaN-based layer are both deposited along a selected growth orientation. The growth orientation is that having the c-axis 15 lying in the growing plane.

Subsequently, the ZnO sacrificial layer 16 is removed by chemical etching. It can be seen from FIG. 1 that, as the ZnO sacrificial layer is etched away, the GaN-based layer 18 starts to crack along the c-axis at regular intervals due to strain redistribution and relaxation, thereby producing a plurality of nanobelt, GaN-based semiconductor structures 12, which may be present as an assembly floating in an acid solution when the ZnO sacrificial layer 16 is completely consumed by the acid.

### Example 2

### A Process to Fabricate an Array of Nanobelt Semiconductor Structures Affixed to a Desired Substrate

Referring to FIG. 1, there is also shown a process 100 to fabricate an array of nanobelt semiconductor structures affixed to a desired substrate in accordance with the present disclosure.

As seen from FIG. 1, the process 100 and method 10 according to the present disclosure have the same initial steps of providing a r-plane sapphire 14, depositing a sacrificial ZnO layer 16 on the sapphire layer 14, followed by a GaN-based layer 18 over the ZnO sacrificial layer 16. Both the ZnO layer 16 and GaN-based layer 18 are deposited along a selected growth orientation in which the growth orientation is that having the c-axis lying in the growing plane.

With the process 100, the GaN-based layer is coated with a black wax forming a coating 20 over the GaN-based layer 18.

After the wax coating, the four-layered structure (comprising r-plane sapphire layer 14, sacrificial ZnO layer 16, GaN-based layer 18 and black wax coating 20) is exposed to an acid to remove the sacrificial layer 16 by wet etching. Etching away the sacrificial layer 16 causes strain redistribution and relaxation in the crystal lattice structure of the GaN-based layer 18, which leads to cracking of the GaN-based layer in directions of growth along a selected in-plane axis of the selected growth orientation, such as the c-axis 15 set out by the r-plane sapphire.

The black wax serves to hold the nanobelt semiconductor structures together in an array as they are formed. This allows the array of the nanobelt semiconductor structures to be transferred as an overall unit and affixed onto a desired substrate 22. Once affixed, the black wax coating 20 can be removed to provide an array of nanobelt semiconductor structures affixed to a desired substrate.

The desired substrate may be selected from the group consisting of sapphire, glass and quartz. The desired substrate can be flexible with conductive coatings such as metal and indium tin oxide.

### Example 3

### Preparation of ZnO Sacrificial Layer on Sapphire Substrates and the Growth of GaN-Based Structures

Two-inch r-plane sapphire substrates are first loaded into a radio-frequency (rf) magnetron sputtering chamber through a load-lock. After a heat treatment at 650° C. for a few hours, the temperature is lowered down to 300° C. to grow a thin low-temperature ZnO buffer layer (˜10 nm), which is followed by an in-situ annealing at 650° C. for 30 minutes in argon ambient and a further growth of ZnO thin film of thickness in the range from 300 nm to 1000 nm at 600° C. The ZnO sacrificial layers can also be prepared using other methods such as pulse laser-assisted deposition, hydrothermal solution deposition, MBE, and MOCVD, or other deposition methods that give a single crystalline ZnO film on an r-plane sapphire. The thickness of ZnO should be varied in the range from 300 nm to 1000 nm which is considered to be suitable as the template for GaInN MOCVD growth. If the ZnO layer is too thin, the wet etching process will take longer. If the ZnO layer is too thick, during MOCVD growth of GaInN the ZnO layer is easy to be etched by ammonia and the GaInN films may peel off during the MOCVD growth.

The prepared ZnO sacrificial layer on r-plane sapphire is loaded into a MOCVD reactor. The substrate is heated up to the temperatures ranging from 400° C. to 600° C. in nitrogen ambient within 5 minutes and the reactor pressure is set to 150 Torr. Next, 20 sccm trimethylgallium (TMGa) and 10 L/min ammonia are fed into the MOCVD reactor simultaneously to start the growth of low-temperature GaN protecting layer. Due to the low growth temperature the GaN growth tends to be three dimensional. To suppress the three dimensional growth and thus enhance the lateral growth, Bis(cyclopentadienyl)magnesium (Cp2Mg) of 200 sccm is fed into the reactor. The Mg atoms work as surfactants that enhance the surface migration of Ga and N adatoms. The Cp2Mg flow is important to suppress the three dimensional growth and achieve a flat surface. The Cp2Mg flow can be varied in the range from 100 sccm to 500 sccm. The Cp2Mg flow can be constant or modulated. When the Cp2Mg flow is modulated, the Cp2Mg flow is introduced into the reactor for certain duration tₒₙ, and then turned off for certain duration t_{off}. The tₒₙ and t_{off} can be varied from 5 seconds to 1 minute. The thickness of the GaN layer is in the range from 30 nm to 150 nm. This low-temperature GaN buffer layer is critical to prevent the ZnO sacrificial layer from decomposing in ammonia ambient at high temperatures. Its thickness needs to be properly chosen since the thin GaN buffer may not protect the ZnO layer well, and a thick GaN buffer may cause deterioration in the quality of the GaInN thin films.

After the growth of low temperature GaN buffer layer, the substrate temperature of the MOCVD reactor is increased to 720° C. within 3 minutes. Trimethylindium (TMIn) is flowed into the reactor together with TMGa and ammonia to start the growth of GaInN thin film. The indium composition can be varied by changing the relative flow ratio of TMIn and TMGa. The growth rate is set to 150 nm per hour. After growth, the substrate temperature of the reactor is cooled down to room temperature. The indium composition can be varied from 0 to 0.4 mole fraction with the GaInN film of high crystal quality. The GaInN film thickness can be varied from a few nanometers to 500 nm while still maintaining mirror-like surface.

FIG. 2 shows a scanning electron microscopy (SEM) image taken from the cross-section of the MOCVD grown GaInN/GaN/ZnO/r-sapphire structure. The layered structures are clearly observed in the image. The thicknesses of the individual layers, as resolved from the SEM image, are 150, 50, and 500 nm for GaInN, GaN, and ZnO, respectively.

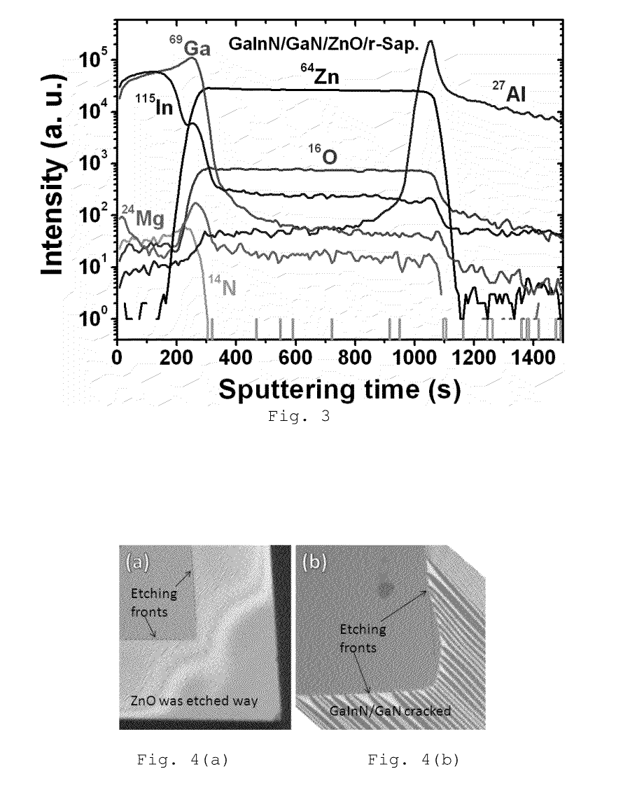

FIG. 3 shows the depth profiles of elements including Ga, In, N, Mg, Zn, O, and Al measured by secondary ion-mass spectrometry from the GaInN/GaN heterostructure grown on ZnO templates by MOCVD. GaInN, GaN:Mg, ZnO and sapphire (Al₂O₃) layers are clearly identified again. The most important observation is that neither zinc nor oxygen atoms out diffusions occurred during the MOCVD growth of the GaN-based structure due to the designed low-temperature GaN buffer technique. Another clear-cut indicator is that the distribution of Mg in the GaN layer is much more than those in its adjacent layers.

### Example 4

### Method to Etch the ZnO Sacrificial Layer and Generate GaInN/GaN Nanobelts

The two-inch wafer composed of an GaInN thin film with a low temperature GaN protecting layer grown on a ZnO sacrificial layer on r-plane sapphire substrate is cut into samples with various shapes and sizes according to the needs. The samples are cleaned by sonication in solvents for further processes.

For generating GaInN/GaN nanobelts assembly, the samples are rinsed directly in HCl or diluted HF solutions, the ZnO templates are etched away and the strain redistribution and relaxation in the GaInN/GaN layered structure cracks the structure along its c-axis to generate nanobelts with the thickness of 200 nm (the thickness of the GaInN layer and the thickness of the LT-GaN protecting layer). The width of the nanobelts is around 10-20 μm, which can be adjusted by changing the thickness of the GaInN/GaN structure. The length of nanobelts is depended on the sample size, which can be as long as centimetres. It is noted that the chemical etching by either HCl or diluted HF does not show any preferred in-plane, i.e., lateral, etching orientation. FIG. 4 shows the evolution of the etching front with the increase of etching time from FIG. 4(a) to FIG. 4(b). It is seen in FIG. 4(a) that the etching fronts are parallel to the sample edges having an angle of nearly 90°. When the etching time is increased in FIG. 4(b) the structure is cracked in the area where the ZnO template was etched away, however, the etching fronts are still nearly perpendicular to each other.

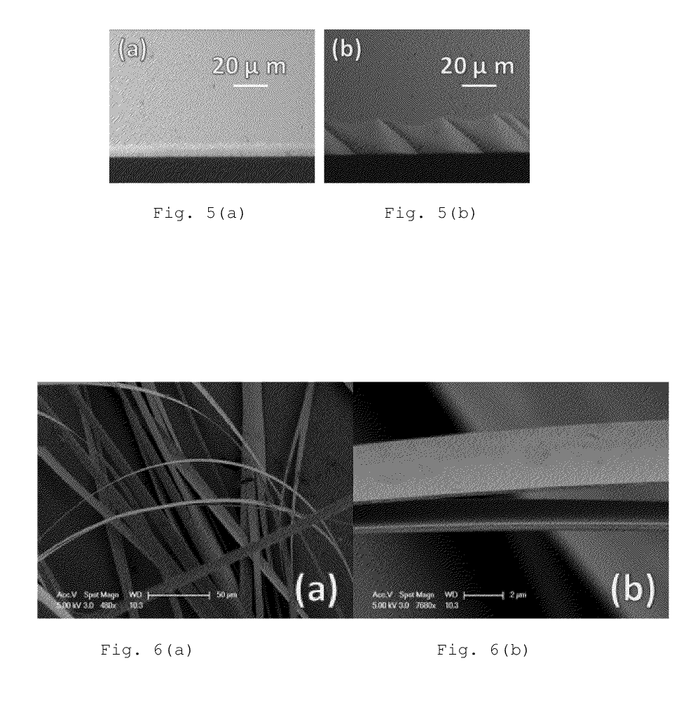

It is also seen in FIG. 4(a) that the initial etching off of the ZnO sacrificial layer does not crack the GaInN/GaN structure. A closer etching time comparison is shown in FIG. 5(a) and FIG. 5(b), where one can see that a light longer etching time in FIG. 5(b) as compare to that for FIG. 5(a) resulted in the deformation (curvatures) in the GaInN/GaN area where the ZnO was etched away.

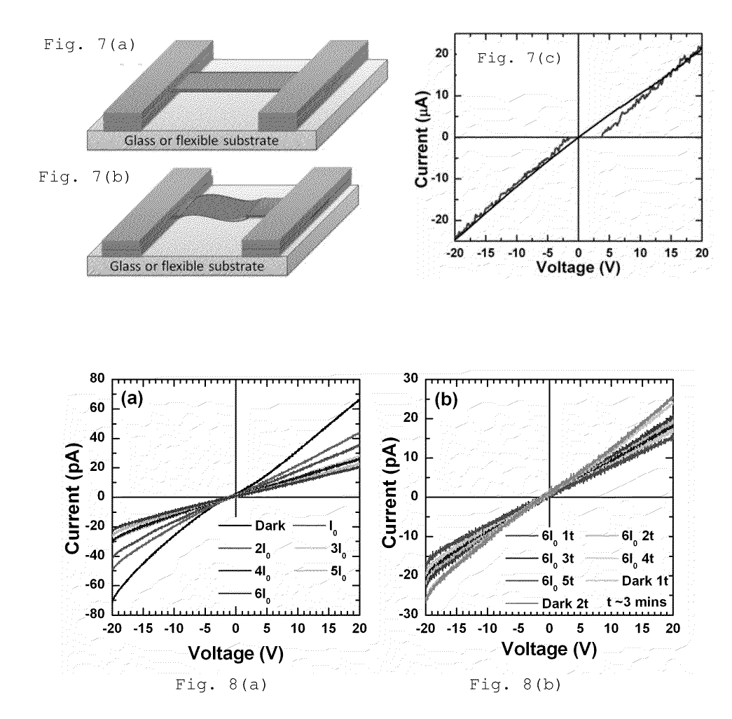

FIG. 6 shows the GaInN/GaN layered nanobelts collected from the solution.

Schematic diagrams of the two-end device using the GaInN/GaN single nanobelt fabricated as discussed above are shown in FIG. 7(a) for twist-free nanobelt and FIG. 7(b) for twisted nanobelt. FIG. 7(c) presents the current-voltage curves measured from a twist-free [FIG. 7(a)] and a twisted [FIG. 7(b)] nanobelts. It is seen that the twist, i.e., strain applied on the nanobelts may cause significant change in the linear current-voltage, mainly due to the novel piezoelectric properties of the nanobelts. It has also been found that the current-voltage curve of the two-end nanobelts device is sensitive to light and can be used as sensors.

Optical and heat sensing of the two-end device is also tested by keeping the nanobelts device under a microscope and changing the intensity of light and also the temperature of the device by the light (from a halogen optic lamp) shining on it. I-V curves were measured as a function of the lighting intensities as well as time durations of lightening (see FIG. 8(a) and FIG. 8(b)).

### Example 5

### A Process to Handle the GaInN/GaN Nanobelts in a Regular Array

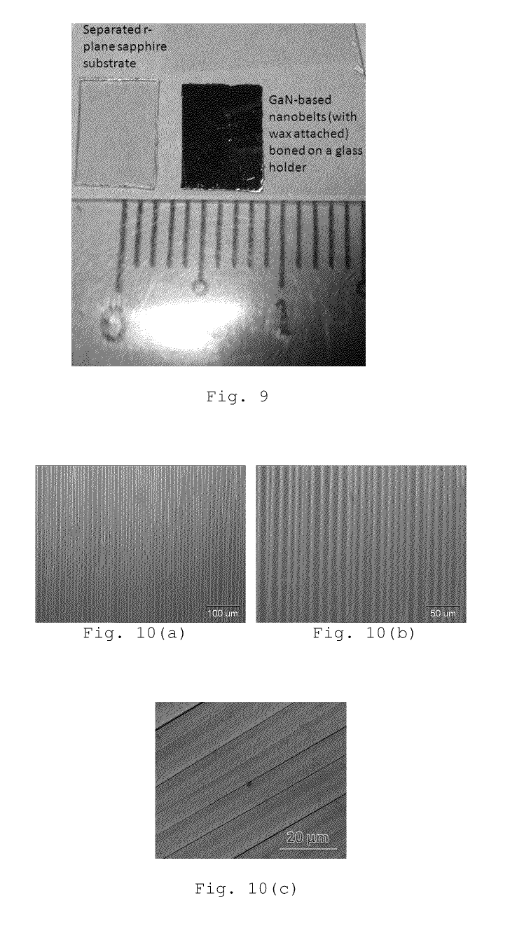

A layer of liquid wax, formed by dissolving black wax in CH₂Cl₂ is coated onto the surface of the sample. It is then baked in order to relax the strain in the wax. Wet etching is next conducted to crack the GaInN/GaN layered structure generating the nanobelts. The nanobelts are lifted off and bonded to a glass holder and the wax is finally removed. The details of the process are described as follows.
(1) The two-inch wafer composed of GaInN/GaN layered structure grown on ZnO sacrificial layer on r-plane sapphire substrate is cut into samples with the various shapes and sizes according to the needs using a diamond scriber. The scribing should be done from the sapphire substrate side to obtain a clean cleaved surface.
(2) The specimen is cleaned by sonication in acetone, followed by methanol and deionized water. The sample is dried using N₂ flow and is oven baked at 110° C. and then cooled down to room temperature.
(3) The liquid wax is coated on to the GaInN thin film surface using a glass tube.
(4) The applied liquid wax is left to solidify in ambient condition for −30 minutes to give a soft wax layer on the specimen. The specimen is then baked at 50° C. in the oven for one and a half hour so as to relax the strain in the wax. After baking, the wax is solidified.
(5) The sample is dipped into 36% HCl solution tank and the ZnO sacrificial layer is etched off by HCl while the GaInN/GaN layers are cracked due to the strain redistribution and relaxation in responding to the release of ZnO. Stirring may accelerate the etch rate. After a few hours, the GaInN/GaN nanobelts in a parallel array with the wax attached are lifted off from the sapphire substrate and float on the HCl solution.
(6) The lifted-off nanobelts which are attached onto the wax are transferred from the acid tank to a beaker filled with water using a glass slide. The manipulation of the lifted-off nanobelts floating on the surface of acid solution or water can be done using a pair of sharp tweezers or a plastic stick. When moving the sample onto the glass slide, the angle between the slide and the water surface should be as small as possible, so that the film (i.e., the wax with nanobelts attached) is not bended by the surface force of the water.
(7) The residual acid on the lifted-off film (i.e., the wax with nanobelts attached) is washed away by transferring the film to another beaker filled with water and repeating the process for several times. The acid has to be removed completely to prevent the corrosion of the holder.
(8) When the residual acid has been completely removed from the lifted-off film (i.e., the wax with nanobelts attached), the film is moved onto a holder with the wax facing upward, following the same steps described in (6) using a pair of sharp tweezers or a plastic stick.
(9) The film is dried on the holder by leaving it in a clean hood for a few minutes. To completely remove the water in the film, a spongy tissue paper can be used to absorb the water.
(10) With the GaInN/GaN nanobelts paralleled array bonded to the holder (as shown in FIG. 9), it is then held in a sealed container of CH₂Cl₂ keeping the sample above the solvent to allow its vapour to dissolve the wax coated on the GaInN/GaN nanobelts. When the wax becomes soft, the GaInN/GaN nanobelts array can be dipped into the CH₂Cl₂ solution to remove the wax completely. The resultant GaInN/GaN nanobelts array bonded on a glass substrate can be seen in FIG. 10(a), FIG. 10(b) and FIG. 10(c).

### Applications

The disclosed methods may produce, in some cases, nanobelt semiconductor structures such as high-quality single crystal GaN-based nanobelts which may be arranged in an array or used in plurality as desired.

The nanobelt semiconductor structures produced from the disclosed method can be used in applications such as a single nanobelt piezoelectric field-effect transistors, single nanobelt piezoelectric diodes, and single nanobelt nanogenerators.

The array of nanobelt semiconductor structures affixed to a desired substrate as produced from the disclosed process may be used in the fabrication of paralleled nanobelts array on flexible substrates for photovoltaic, sensors, and detector applications.

The technology developed herein relating to strain-controlled cracking of thin-solid films into nanobelts can also be used to fabricate other semiconductor nanobelts such as InGaAs on GaAs (110) using AlAs as a sacrificial template and SiGe on Si (110) using n-Si as a sacrificial template.

The nanobelts may be used to fabricate nano-sized semiconductor optical fiber and parallel fiber array by (1) adjusting the optical refractive index of the GaN as well as its heterostructure nanobelts by doping and/or composition engineering and/or 2) coat the nanobelts with optical materials to guide the light (with a certain wavelength) within the nanobelts.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A method to fabricate longitudinally-shaped structures, the method comprising
a) providing a substrate selected to promote epitaxial growth thereon along a selected growth orientation,
b) depositing a crystalline sacrificial layer on the substrate for expitaxial growth along the selected growth orientation,
c) forming a film over the sacrificial layer, the film having a crystal lattice structure grown substantially along the selected growth orientation, and
d) removing at least part of the sacrificial layer, thereby producing the longitudinally shaped structures from the film by causing strain redistribution through the crystal lattice structure of the film to crack the film along a selected in-plane axis of the selected growth orientation.

2. A method according to claim 1, wherein the strain redistribution is through crystal lattice relaxation.

3. A method according to claim 1, wherein the longitudinally-shaped structures are semiconductor nanobelt structures.

4. A method according to claim 1, wherein the film has a thickness in the range of 50 to 250 nm.

5. A method according to claim 1, wherein the sacrificial layer has a thickness in the range of 250 to 1200 nm.

6. A method according to claim 1, wherein the substrate is selected from the group consisting of an r-plane sapphire substrate, a spinal silicon substrate, an a-plane GaN wafer, a m-plane GaN wafer and a GaN/r-sapphire.

7. A method according to claim 1, wherein the sacrificial layer is Zinc Oxide.

8. A method according to claim 1, wherein the selected growth orientation is along the c-axis lying in the growing plane.

9. A method according to claim 1, wherein step c) comprises the step of first forming a protective film over the sacrificial layer.

10. A method according to claim 9, wherein step c) further comprises the step of growing the film and incorporating a functionally active element to thereby form a functionally active film.

11. A method according to claim 10, comprising the step of selecting the GaN/GaInN film as the functionally active film.

12. A method according to claim 9, comprising the step of selecting a Group III metal-nitride as the protective film.

13. A method according to claim 12, comprising the step of forming the protective film at a temperature selected from the range of 350° C. to 650° C.

14. A method according to claim 13, comprising the step of providing a growth suppressing agent in the protective film formation step to suppress the three dimensional growth of the GaN film.

15. A method according to claim 1, wherein the removing step comprises etching the sacrificial layer.

16. A method according to claim 1, wherein before the removing step, the method comprises the step of applying a substrate having adhesive properties to the film on said sacrificial layer.

17. A method according to claim 16, wherein the applying step comprises the step of coating a surface of the film with a wax in liquid form that forms a wax substrate having adhesive properties when cooled to a solid phase.

18. A method according to claim 17, comprising the step of affixing longitudinally-shaped structures with the wax substrate onto a desired substrate.

19. A method according to claim 17, comprising the step of removing the wax substrate to provide an array of longitudinally-shaped structures affixed to the desired substrate.

20. A device comprising a plurality or an array of nanobelt semiconductor structures obtained from claim 1.
